(19) United States
(12) Patent Application Publication
(10) Pub. No.: US 2013/0088237 A1
(43) Pub. Date: Apr. 11, 2013

(54) BATTERY-MONITORING DEVICE

(71) Applicant: KEIHIN CORPORATION, Tokyo (JP)

(72) Inventors: Seiji KAMATA, Shioya-gun (JP); Hidefumi ABE, Shioya-gun (JP)

(73) Assignee: KEIHIN CORPORATION, Tokyo (JP)

(21) Appl. No.: 13/644,032

(22) Filed: Oct. 3, 2012

(30) Foreign Application Priority Data
Oct. 7, 2011 (JP) 2011-222858

(51) Int. Cl. G01R 31/36

(52) U.S. Cl. 324/434

(57) ABSTRACT

The present invention provides a battery-monitoring device is provided that monitors a voltage state of each battery cell constituting a battery, including: a voltage detection circuit; a management circuit which manages voltage detection data of each battery cell using the voltage detection circuit; a communication mode converter which is connected to the voltage detection circuit through a first communication line for communicating using a clock synchronous communication mode, and is connected to the management circuit through a second communication line for communicating using a clock asynchronous communication mode; and an insulating element which is interposed in the second communication line, wherein the communication mode converter transmits the voltage detection data, received from each of the voltage detection circuits through the first communication line, through the second communication line to the management circuit.

### BACKGROUND OF THE INVENTION

1. Field of the Invention

The present invention relates to a battery-monitoring device.

Priority is claimed on Japanese Patent Application No. 2011-222858, filed on Oct. 7, 2011, the content of which is incorporated herein by reference.

2. Description of Related Art

As is well known, a motor which is used as a source of power, and a high voltage and capacity battery that supplies power to the motor are mounted to vehicles such as an electric automobile and a hybrid automobile. The high-voltage battery is configured such that a plurality of battery cells formed of a lithium-ion battery, a nickel-hydrogen-battery or the like are connected to each other in series.

The high-voltage battery is divided into a plurality of blocks, and is provided with a voltage detection circuit (for example, a dedicated IC chip) that detects a voltage of a battery cell for each block. Each voltage detection circuit is connected so as to be capable of communicating with a low-voltage system micro-controller that manages voltage detection data of each battery cell through an insulating element, and transmits the voltage detection data of a battery cell belonging to each block to the low-voltage system micro-controller (see Japanese Unexamined Patent Application, First Publication No. 2009-17663).

As mentioned above, in the related art, since the voltage detection circuit (high-voltage system) and a low-voltage system micro-controller which have different power systems are connected to each other through the insulating element, a large number of insulating elements capable of coping with high-speed multiple communication lines are required, and thus there has been a problem in that an increase in component costs is caused.

The invention is contrived in view of such circumstances, and an object thereof is to provide a battery-monitoring device which is capable of achieving a reduction in costs by reducing the number of insulating elements.

### SUMMARY OF THE INVENTION

The present invention employs the following configuration to solve the above problems.

(1) According to a first aspect of the invention, a battery-monitoring device is provided that monitors a voltage state of each battery cell constituting a battery, including: a voltage detection circuit, provided for each block obtained by dividing the battery into multiple parts, which detects a voltage of the battery cell belonging to each block; a management circuit, belonging to a power system having a voltage lower than that of a power system of the voltage detection circuit, which manages voltage detection data of each battery cell using the voltage detection circuit; a communication mode converter, belonging to the same power system as that of the voltage detection circuit, which is connected to the voltage detection circuit through a first communication line for communicating using a clock synchronous communication mode, and is connected to the management circuit through a second communication line for communicating using a clock asynchronous communication mode; and an insulating element which is interposed in the second communication line, wherein the communication mode converter transmits the voltage detection data, received from each of the voltage detection circuits through the first communication line, through the second communication line to the management circuit.

(2) In the battery-monitoring device according to the above (1), the voltage detection circuits may be connected to each other in a daisy-chain manner, and the communication mode converter may be connected to one of the voltage detection circuits through the first communication line.

(3) In the battery-monitoring device according to the above (2), the communication mode converter may include a memory for data storage.

(4) In the battery-monitoring device according to the above (3), the clock synchronous communication mode may be an SPI, and the clock asynchronous communication mode may be a UART.

(5) In the battery-monitoring device according to the above (1), the communication mode converter may include a memory for data storage.

(6) In the battery-monitoring device according to the above (1), the clock synchronous communication mode may be an SPI, and the clock asynchronous communication mode may be a UART.

(7) In the battery-monitoring device according to the above (2), the clock synchronous communication mode may be an SPI, and the clock asynchronous communication mode may be a UART.

### BRIEF DESCRIPTION OF THE DRAWINGS

FIG. 1 is a schematic configuration diagram illustrating a battery-monitoring device A according to the present embodiment.

FIG. 2 is a flow diagram illustrating operations at the time of reprogramming.

### DETAILED DESCRIPTION OF THE INVENTION

Hereinafter, an embodiment of the invention will be described with reference to the accompanying drawings.

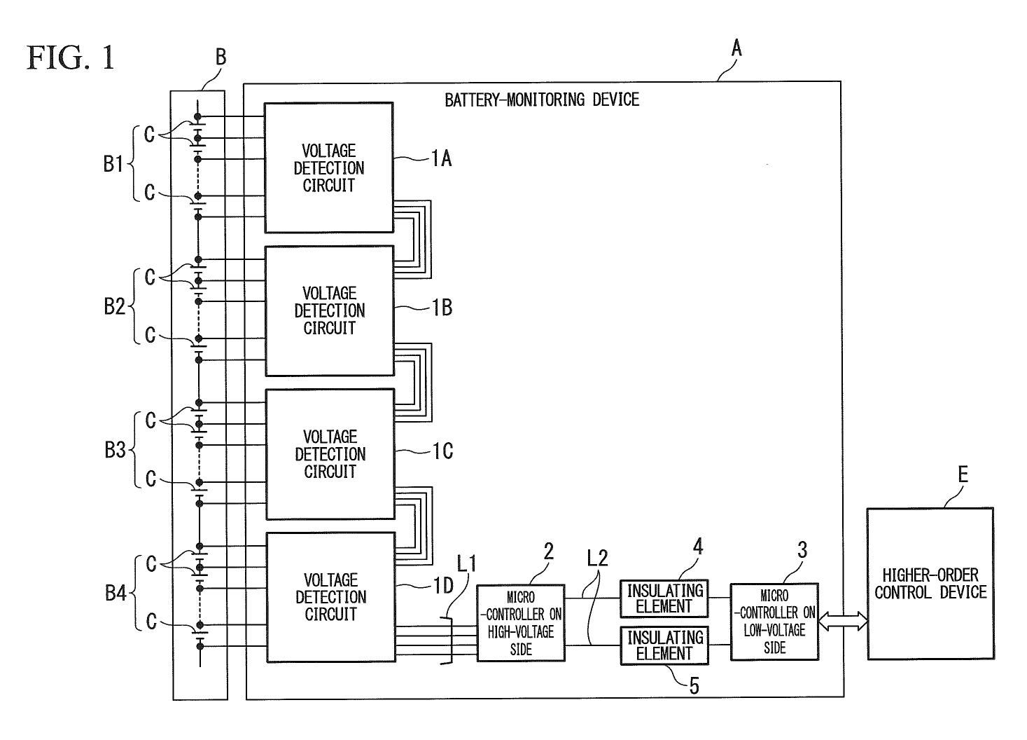

FIG. 1 is a schematic configuration diagram illustrating a battery-monitoring device A according to the present embodiment. The battery-monitoring device A is used for monitoring the voltage state of each battery cell C constituting a high-voltage battery B, and includes four voltage detection circuits 1A, 1B, 1C, and 1D, a micro-controller 2 on the high-voltage side, a micro-controller 3 on the low-voltage side, and two insulating elements 4 and 5, as shown in FIG. 1. Meanwhile, the voltage detection circuits 1A, 1B, 1C, and 1D and the micro-controller 2 on the high-voltage side are circuits belonging to a power system on the high-voltage side, and the micro-controller 3 on the low-voltage side is a circuit belonging to a power system on the low-voltage side.

The high-voltage battery B is divided into four blocks B1 to B4. The voltage detection circuit 1A is provided corresponding to the block B1, the voltage detection circuit 1B is provided corresponding to the block B2, the voltage detection circuit 1C is provided corresponding to the block B3, and the voltage detection circuit 1D is provided corresponding to the block B4.

The voltage detection circuits 1A, 1B, 1C, and 1D are dedicated IC chips that detect a voltage of the battery cell C belonging to each block and have an A/D conversion function of converting the detection result into digital data (voltage detection data) or a function of communication with the micro-controller 2 on the high-voltage side. The voltage detection circuits 1A, 1B, 1C, and 1D are connected to each other in a daisy-chain manner, and the foremost-stage voltage detection circuit 1D is connected to the micro-controller 2 on the high-voltage side through an SPI communication line L1.

The micro-controller 2 on the high-voltage side is an IC chip in which a CPU (Central Processing Unit), memory, an input and output interface, and the like are integrally incorporated, and belongs to the same power system on the high-voltage side as the voltage detection circuits 1A, 1B, 1C, and 1D. The micro-controller 2 on the high-voltage side is connected to the voltage detection circuit 1D through the SPI communication line L1 (first communication line) for communicating using an SPI (Serial Peripheral Interface) which is one clock synchronous communication mode, and is connected to the micro-controller 3 on the low-voltage side through a UART communication line L2 (second communication line) for communicating using a UART (Universal Asynchronous Receiver Transmitter) which is one clock asynchronous communication mode.

As is well known, the SPI is a three-wire serial communication mode for transmitting data while synchronizing with a clock. That is, the SPI communication line L1 that couples the micro-controller 2 on the high-voltage side to the voltage detection circuit 1D is constituted by a total of four communication lines of a clock line, a chip selector line and data lines (two for bidirectional communication). Therefore, the voltage detection circuits 1A, 1B, 1C, and 1D connected to each other in a daisy-chain manner are also connected by four communication lines, respectively.

On the other hand, the UART is an asynchronous serial communication mode for transmitting data using start-stop synchronous communication. That is, the UART communication line L2 that couples the micro-controller 2 on the high-voltage side and the micro-controller 3 on the low-voltage side is constituted by a total of two communication lines of a transmission data line (TX) and a receiving data line (RX).

Such a micro-controller 2 on the high-voltage side has a function as a communication mode converter that transmits voltage detection data, received from each of the voltage detection circuits 1A, 1B, 1C, and 1D through the SPI communication line L1, through the UART communication line L2 to the micro-controller 3 on the low-voltage side, and transmits control data (for example, a command and the like), received from the micro-controller 3 on the low-voltage side through the UART communication line L2, through the SPI communication line L1 to each of the voltage detection circuits 1A, 1B, 1C, and 1D.

The micro-controller 3 on the low-voltage side is an IC chip in which a CPU, a memory, an input and output interface and the like are integrally incorporated, and belongs to a power system having a voltage lower than that of a power system of the voltage detection circuits 1A, 1B, 1C, and 1D and the micro-controller 2 on the high-voltage side. The micro-controller 3 on the low-voltage side has a function as a management circuit that transmits control data through the UART communication line L2 to the micro-controller 2 on the high-voltage side, and manages voltage detection data received from the micro-controller 2 on the high-voltage side through the UART communication line L2.

In addition, the micro-controller 3 on the low-voltage side is connected so as to be capable of communicating with a higher-order control device E disposed at the outside, and also has a function of executing a predetermined process in accordance with instructions from the higher-order control device E, or transmitting voltage detection data collected from each of the voltage detection circuits 1A, 1B, 1C, and 1D through the micro-controller 2 on the high-voltage side to the higher-order control device E.

The insulating element 4 is, for example, a photo-coupler, and is interposed in one of two communication lines constituting the UART communication line L2. Similarly, the insulating element 5 is, for example, a photo-coupler, and is interposed in the other of two communication lines constituting the UART communication line L2. A circuit belonging to the power system on the high-voltage side and a circuit belonging to the power system on the low-voltage side are electrically insulated from each other by providing these insulating elements 4 and 5.

Next, operations of the battery-monitoring device A having the above-mentioned configuration will be described.

### <Operation at the Time of Voltage Detection>

First, operations at the time of voltage detection will be described. When the voltage detection timing comes, the micro-controller 3 on the low-voltage side transmits a command for instructing the voltage detection circuit 1A to detect a voltage through the UART communication line L2 to the micro-controller 2 on the high-voltage side. The micro-controller 2 on the high-voltage side transmits the command, received from the micro-controller 3 on the low-voltage side through the UART communication line L2, through the SPI communication line L1 to each of the voltage detection circuits 1A, 1B, 1C, and 1D.

When it is recognized that the above-mentioned command is a command addressed to itself on the basis of a chip selector signal, the voltage detection circuit 1A fetches the above-mentioned command to analyze instructions of the micro-controller 3 on the low-voltage side, detects a voltage of the battery cell C belonging to the block B1 in accordance with the instructions, and converts the detection result into voltage detection data. The voltage detection circuit 1A transmits the obtained voltage detection data through the voltage detection circuits 1B, 1C, and 1D and the SPI communication line L1 to the micro-controller 2 on the high-voltage side.

The micro-controller 2 on the high-voltage side transmits the voltage detection data, received from the voltage detection circuit 1A through the SPI communication line L1, through the UART communication line L2 to the micro-controller 3 on the low-voltage side. When the voltage detection data is received from the micro-controller 2 on the high-voltage side through the UART communication line L2, the micro-controller 3 on the low-voltage side stores the voltage detection data in an internal memory in association with the battery cell C of the block B1.

Subsequently, the micro-controller 3 on the low-voltage side transmits a command for instructing the voltage detection circuit 1B to detect a voltage through the UART communication line L2 to the micro-controller 2 on the high-voltage side. The micro-controller 2 on the high-voltage side transmits the command, received from the micro-controller 3 on the low-voltage side through the UART communication line L2, through the SPI communication line L1 to each of the voltage detection circuits 1A, 1B, 1C, and 1D.

When it is recognized that the above-mentioned command is a command addressed to itself on the basis of a chip selector signal, the voltage detection circuit 1B fetches the above-mentioned command to analyze instructions of the micro-controller 3 on the low-voltage side, detects a voltage of the battery cell C belonging to the block B2 in accordance with the instructions, and converts the detection result into voltage detection data. The voltage detection circuit 1B transmits the obtained voltage detection data through the voltage detection circuits 1C and 1D and the SPI communication line L1 to the micro-controller 2 on the high-voltage side.

The micro-controller 2 on the high-voltage side transmits the voltage detection data, received from the voltage detection circuit 1B through the SPI communication line L1, through the UART communication line L2 to the micro-controller 3 on the low-voltage side. When the voltage detection data is received from the micro-controller 2 on the high-voltage side through the UART communication line L2, the micro-controller 3 on the low-voltage side stores the voltage detection data in an internal memory in association with the battery cell C of the block B2.

Subsequently, the micro-controller 3 on the low-voltage side transmits a command for instructing the voltage detection circuit 1C to detect a voltage through the UART communication line L2 to the micro-controller 2 on the high-voltage side. The micro-controller 2 on the high-voltage side transmits the command, received from the micro-controller 3 on the low-voltage side through the UART communication line L2, through the SPI communication line L1 to each of the voltage detection circuits 1A, 1B, 1C, and 1D.

When it is recognized that the above-mentioned command is a command addressed to itself on the basis of a chip selector signal, the voltage detection circuit 1C fetches the above-mentioned command to analyze instructions of the micro-controller 3 on the low-voltage side, detects a voltage of the battery cell C belonging to the block B3 in accordance with the instructions, and converts the detection result into voltage detection data. The voltage detection circuit 1C transmits the obtained voltage detection data through the voltage detection circuit 1D and the SPI communication line L1 to the micro-controller 2 on the high-voltage side.

The micro-controller 2 on the high-voltage side transmits the voltage detection data, received from the voltage detection circuit 1B through the SPI communication line L1, through the UART communication line L2 to the micro-controller 3 on the low-voltage side. When the voltage detection data is received from the micro-controller 2 on the high-voltage side through the UART communication line L2, the micro-controller 3 on the low-voltage side stores the voltage detection data in an internal memory in association with the battery cell C of the block B3.

Subsequently, the micro-controller 3 on the low-voltage side transmits a command for instructing the voltage detection circuit 1D to detect a voltage through the UART communication line L2 to the micro-controller 2 on the high-voltage side. The micro-controller 2 on the high-voltage side transmits the command, received from the micro-controller 3 on the low-voltage side through the UART communication line L2, through the SPI communication line L1 to each of the voltage detection circuits 1A, 1B, 1C, and 1D.

When it is recognized that the above-mentioned command is a command addressed to itself on the basis of a chip selector signal, the voltage detection circuit 1D fetches the above-mentioned command to analyze instructions of the micro-controller 3 on the low-voltage side, detects a voltage of the battery cell C belonging to the block B4 in accordance with the instructions, and converts the detection result into voltage detection data. The voltage detection circuit 1D transmits the obtained voltage detection data through the SPI communication line L1 to the micro-controller 2 on the high-voltage side.

The micro-controller 2 on the high-voltage side transmits the voltage detection data, received from the voltage detection circuit 1B through the SPI communication line L1, through the UART communication line L2 to the micro-controller 3 on the low-voltage side. When the voltage detection data is received from the micro-controller 2 on the high-voltage side through the UART communication line L2, the micro-controller 3 on the low-voltage side stores the voltage detection data in an internal memory in association with the battery cell C of the block B4.

It is possible to collect voltage detection data of each battery cell C constituting the battery B, through such an operation, whenever the voltage detection timing comes. Meanwhile, the micro-controller 3 on the low-voltage side may transmit the voltage detection data stored in an internal memory to the higher-order control device E, in accordance with the instructions of the higher-order control device E.

### <Operation at the Time of Reprogramming>

Next, operations at the time of reprogramming will be described. Meanwhile, the term “reprogramming” herein indicates rewriting of existing data (program or the like) stored in the higher-order control device E, the micro-controller 2 on the high-voltage side or the micro-controller 3 on the low-voltage side of the battery-monitoring device A.

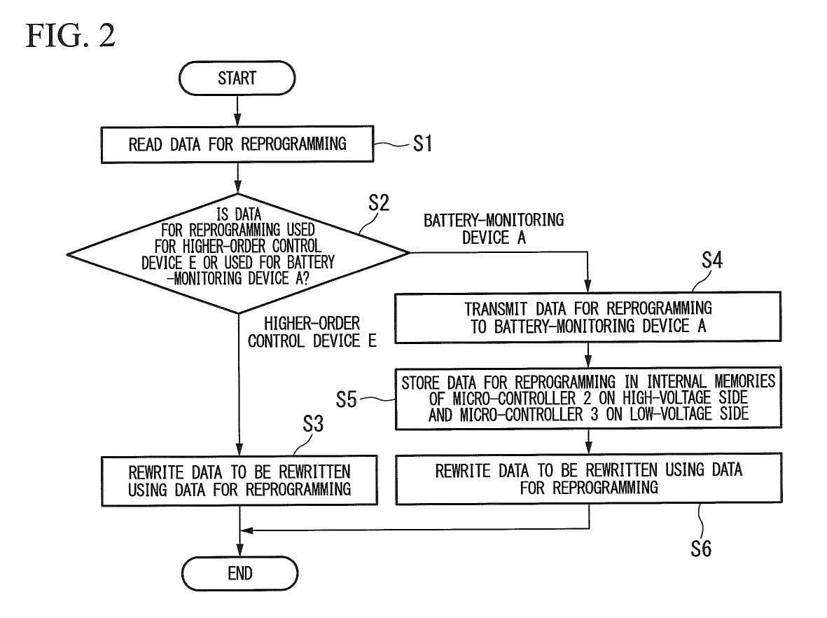

As shown in FIG. 2, the higher-order control device E reads data for reprogramming from a rewriting device for reprogramming which is not shown (step S1), and determines whether the data for reprogramming (data for rewriting) is for the higher-order control device E or is for the battery-monitoring device A (step S2). When it is determined in the above-mentioned step S2 that the data for reprogramming is for the higher-order control device E, the higher-order control device E rewrites data to be rewritten using this data for reprogramming (step S3).

On the other hand, when it is determined in the above-mentioned step S2 that the data for reprogramming is for the battery-monitoring device A, the higher-order control device E transmits this data for reprogramming to the battery-monitoring device A (step S4). In the battery-monitoring device A, the micro-controller 3 on the low-voltage side or the micro-controller 2 on the high-voltage side temporarily stores the data for reprogramming in an internal memory (step S5), and thereafter, rewrites data to be rewritten using the data for reprogramming stored in the internal memory (step S6).

In this manner, at the time of reprogramming, the rewriting processes of the higher-order control device E and the battery-monitoring device A are bifurcated in accordance with the data for reprogramming which is read from the rewriting device for reprogramming, and reprogramming operations of the higher-order control device E and the battery-monitoring device A are separated from each other, thereby allowing the reprogramming operation time to be shortened.

As described above, according to the present embodiment, since a configuration is adopted in which the voltage detection data obtained by each of the voltage detection circuits 1A, 1B, 1C, and 1D provided for each block of the high-voltage battery B is transmitted to the micro-controller 3 on the low-voltage side by way of the micro-controller 2 on the high-voltage side, it is possible to achieve a reduction in costs by reducing the number of insulating elements 4 and 5 (the number thereof may be two). In addition, since the micro-controller 2 on the high-voltage side transmits the voltage detection data to the micro-controller 3 on the low-voltage side using a UART which is one relatively low-speed clock asynchronous communication mode, it is possible to use the inexpensive insulating elements 4 and 5 for low speed.

Meanwhile, the invention is not limited to the above-mentioned embodiment, and includes the following modified example.

For example, in the above-mentioned embodiment, although a case in which the high-voltage battery B is divided into four blocks B1 to B4 is illustrated by way of example, the invention is not limited thereto, and the number of voltage detection circuits may be appropriately changed in accordance with the number of blocks of the high-voltage battery B.

In addition, in the above-mentioned embodiment, although a case in which an SPI is used as a clock synchronous communication mode and a UART is used as a clock asynchronous communication mode is illustrated by way of example, other communication modes may be adopted.

In addition, in the above-mentioned embodiment, although a case in which the voltage detection circuits 1A, 1B, 1C, and 1D are connected to each other in a daisy-chain manner is illustrated by way of example, a bus connection-type configuration may be adopted in which the voltage detection circuits 1A, 1B, 1C, and 1D are connected to the SPI communication line L1 in parallel.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A battery-monitoring device that monitors a voltage state of each battery cell constituting a battery, comprising:
a voltage detection circuit, provided for each block obtained by dividing the battery into multiple parts, which detects a voltage of the battery cell belonging to each block;
a management circuit, belonging to a power system having a voltage lower than that of a power system of the voltage detection circuit, which manages voltage detection data of each battery cell using the voltage detection circuit;
a communication mode converter, belonging to the same power system as that of the voltage detection circuit, which is connected to the voltage detection circuit through a first communication line for communicating using a clock synchronous communication mode, and is connected to the management circuit through a second communication line for communicating using a clock asynchronous communication mode; and
an insulating element which is interposed in the second communication line,
wherein the communication mode converter transmits the voltage detection data, received from each of the voltage detection circuits through the first communication line, through the second communication line to the management circuit.

2. The battery-monitoring device according to claim 1, wherein the voltage detection circuits are connected to each other in a daisy-chain manner, and
the communication mode converter is connected to one of the voltage detection circuits through the first communication line.

3. The battery-monitoring device according to claim 2, wherein the communication mode converter includes a memory for data storage.

4. The battery-monitoring device according to claim 3, wherein the clock synchronous communication mode is an SPI, and the clock asynchronous communication mode is a UART.

5. The battery-monitoring device according to claim 1, wherein the communication mode converter includes a memory for data storage.

6. The battery-monitoring device according to claim 1, wherein the clock synchronous communication mode is an SPI, and the clock asynchronous communication mode is a UART.

7. The battery-monitoring device according to claim 2, wherein the clock synchronous communication mode is an SPI, and the clock asynchronous communication mode is a UART.
